(19) United States
(12) Patent Application Publication
(10) Pub. No.: US 2017/0264313 A1
(43) Pub. Date: Sep. 14, 2017

(54) LOW COMPLEXITY DECODER AND DECODING METHOD BASED ON CODE OF BIT NODE

(71) Applicant: Electronics and Telecommunications Research Institute, Daejeon (KR)

(72) Inventors: In Ki LEE, Daejeon (KR); Min Hyuk KIM, Daejeon (KR)

(73) Assignee: Electronics and Telecommunications Research Institute, Daejeon (KR)

(21) Appl. No.: 15/452,906

(22) Filed: Mar. 8, 2017

(30) Foreign Application Priority Data
Mar. 9, 2016 (KR) 10-2016-0028386

(51) Int. Cl. H03M 13/11; H03M 13/00

(52) U.S. Cl. CPC H03M 13/1105; H03M 13/118; H03M 13/6522; H03M 13/1131

(57) ABSTRACT

Provided is a decoder that is at least temporarily implemented by a processor of a computing device. The decoder includes a calculator configured to repeatedly perform a calculation of a bit node and a calculation of a check node for an input frame, a processor configured to determine whether to input the bit node to a next calculation of the check node based on a code of the bit node, and an outputter configured to output a decoded code based on the bit node determined to be input.

### CROSS-REFERENCE TO RELATED APPLICATION

This application claims the benefit of Korean Patent Application No. 10-2016-0028386, filed on Mar. 9, 2016, in the Korean Intellectual Property Office, the disclosure of which is incorporated herein by reference.

### BACKGROUND

1. Field of the Invention

One or more example embodiments relate to low complexity decoding based on a code of a bit node, and more particularly, to decoding for enhancing a performance and reducing an amount of decoding calculation by changing a reliability of a bit node based on a change in a code of the bit node.

2. Description of the Related Art

An error correcting code applicable to broadband satellite broadcasting may include, for example, a concatenated code applied to a digital video broadcasting-satellite (DVB-S), a turbo code applied to a digital video broadcasting return channel by satellite (DVB-RCS), and a low-density parity-check (LDPC) code applied to a digital video broadcasting-satellite-second generation (DVB-S2). In a DVB-S2 standard that is a satellite broadcasting transmission standard, an LDPC code may be employed as a forward error correction (FEC) technology, and the LDPC code, that is one of repetition codes, may correspond to the FEC technology that is applied as an error correction technology in a broadcasting communication transmission standard, for example, a DVB-T2, in addition to the DVB-S2. The concatenated code may acquire a high coding gain and is relatively greatly different from a Shannon's Limit in a performance or channel error control scheme that is in the limelight in a wireless communication system. Accordingly, a turbo code with a performance close to that of the concatenated code was published by Berrou, and the like, in 1993. Since the present task relates to broadband satellite broadcasting at levels of 100 megabits per second (Mbps) or higher, it is impossible to apply the turbo code. Accordingly, it is indispensable to apply a decoder that is efficient and excellent in performance to a high speed data transmission. Also, an LDPC coding scheme provided in the DVB-S2 is suitable as a high-speed satellite broadcasting transmission technology of 100 Mbps or higher to provide ultra high definition multi-channel realistic broadcasting services in a national unit. An LDPC code close to a Shannon's channel capacity limit that is applied to the DVB-S2 as an European satellite broadcasting standard has a complexity of decoding less than that of a turbo code, and an error floor phenomenon does not occur due to a good distance characteristic. Also, it is advantageous that high speed processing is enabled as fully parallel processing.

The above LDPC code is used to correct an error by repeatedly performing a calculation of a check node and a calculation of a bit node when decoding is performed at a receiver. However, since the LDPC has relatively long codewords, for example, 64,800 bits, in the DVB-S2, an amount of calculation is complex.

### SUMMARY

According to an aspect, there is provided a decoder that is at least temporarily implemented by a processor of a computing device, the decoder including a calculator configured to repeatedly perform a calculation of a bit node and a calculation of a check node for an input frame, a processor configured to determine whether to input the bit node to a next calculation of the check node based on a code of the bit node, and an outputter configured to output a decoded code based on the bit node determined to be input.

The processor may be further configured to determine the bit node by checking a number of repetitions of the calculation of the check node and the calculation of the bit node. The processor may be further configured to repeatedly perform the calculations until the number of repetitions reaches a threshold. When the code is reversed, the bit node may be determined not to be input to the next calculation of the check node. The processor may be further configured to compare a code of the bit node in a current number of repetitions and a code of the bit node in a previous number of repetitions. A bit node in which a code is not reversed may be input to the next calculation of the check node. The code may be generated based on a parity check matrix. The decoder may further include a memory configured to store the input frame.

According to another aspect, there is provided a decoding method including repeatedly performing a calculation of a bit node and a calculation of a check node for an input frame, determining whether to input the bit node to a next calculation of the check node based on a code of the bit node, and outputting a decoded code based on the bit node determined to be input.

The decoding method may further include determining the bit node by checking a number of repetitions of the calculation of the check node and the calculation of the bit node. The decoding method may further include repeatedly performing the calculations until the number of repetitions reaches a threshold. The decoding method may further include, when the code is reversed, determining not to input the bit node to the next calculation of the check node. The decoding method may further include comparing a code of the bit node in a current number of repetitions and a code of the bit node in a previous number of repetitions. The decoding method may further include inputting a bit node in which a code is not reversed to the next calculation of the check node. The decoding method may further include generating the code based on a parity check matrix. The decoding method may further include storing the input frame in a memory. A non-transitory computer-readable storage medium storing a program for causing a processor to perform the decoding method may be provided.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a flowchart illustrating a decoding algorithm based on a code of a bit node according to an example embodiment;

FIG. 2 is a block diagram illustrating an internal configuration of a decoder according to an example embodiment;

FIG. 3 is a diagram illustrating an example of a structure in which a calculation of a check node is performed according to an example embodiment;

FIG. 4 is a diagram illustrating an example of a structure in which a calculation of a bit node is performed according to an example embodiment;

FIG. 5 is a block diagram illustrating an internal configuration of a decoder according to an example embodiment;

FIG. 6 is a flowchart illustrating an example of a decoding method according to an example embodiment; and

FIG. 7 is a flowchart illustrating another example of a decoding method according to an example embodiment.

### DETAILED DESCRIPTION

The following structural or functional descriptions of example embodiments described herein are merely intended for the purpose of describing the example embodiments described herein and may be implemented in various forms. However, it should be understood that these examples are not construed as limited to the illustrated forms and include all changes, equivalents or alternatives within the idea and the technical scope of this disclosure.

Although terms of “first,” “second,” and the like are used to explain various components, the components are not limited to such terms. These terms are used only to distinguish one component from another component. For example, a first component may be referred to as a second component, or similarly, the second component may be referred to as the first component within the scope of the present invention.

When it is mentioned that one component is “connected” or “accessed” to another component, it may be understood that the one component is directly connected or accessed to another component or that still other component is interposed between the two components.

As used herein, the singular forms “a”, “an”, and “the” are intended to include the plural forms as well, unless the context clearly indicates otherwise. It will be further understood that the terms “include/comprise” and/or “have” when used in this specification, specify the presence of stated features, integers, steps, operations, elements, components, and/or combinations thereof, but do not preclude the presence or addition of one or more other features, numbers, steps, operations, elements, components, and/or groups thereof.

Unless otherwise defined, all terms including technical and scientific terms used herein have the same meaning as commonly understood by one of ordinary skill in the art to which examples belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

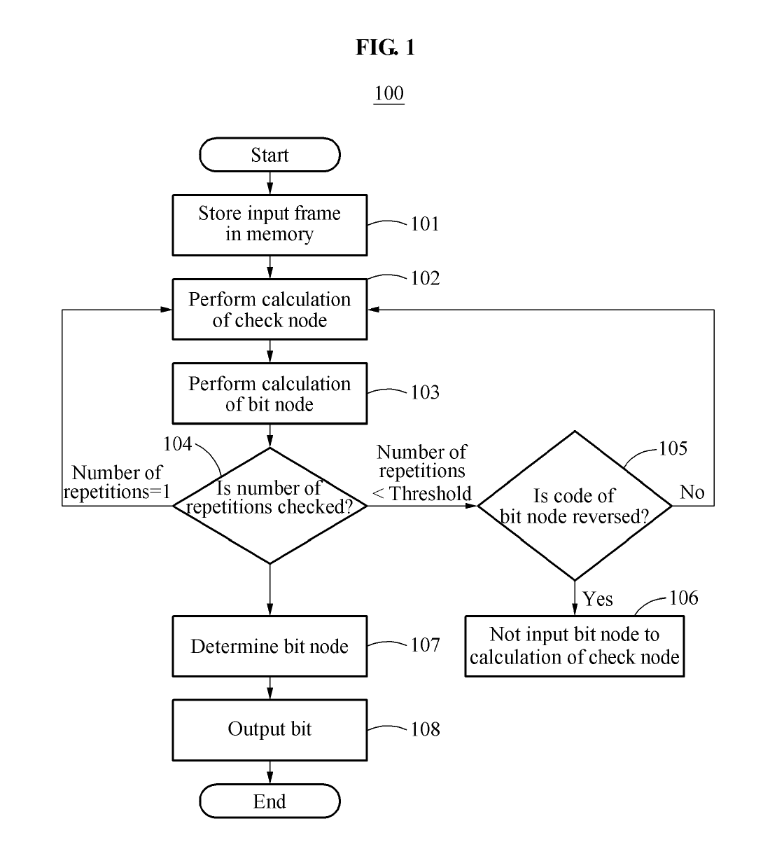

FIG. 1 is a flowchart illustrating a decoding algorithm based on a code of a bit node according to an example embodiment.

A low-density parity-check (LDPC) code based on a digital video broadcasting-satellite-second generation (DVB-S2) may be generated by a parity check matrix H using only “0” and “1.” In the parity check matrix H, locations of “1” may be very rarely, randomly distributed. Due to the above properties, the LDPC code may be excellent in performance, however, a large amount of calculation may be generated due to a large block and a large number of repetitions. An LDPC code based on a DVB-S2 standard may be segmented due to a structure of a matrix, and accordingly parallel calculations by a size of the segmented LDPC code may be enabled. Thus, parallel calculations corresponding to a size of the segmentation in the matrix H may be performed, and a speed may be increased. However, due to a large number of parallel calculations, an amount of calculation may also increase, which may lead to an increase in a clock cycle. In particular, a block size in the DVB-S2 standard may be “64,800” and edges of about “6” through “20” may be connected for each node, and accordingly a large amount of calculation required for a single repetitive calculation. To prevent an increase in the amount of calculation as described above, the present disclosure may provide a scheme of determining a reduction in a reliability of a bit decrease in response to a change in a code of the bit when monitoring a code of a bit node in a current number of repetitions and a code of the bit node in a previous number of repetitions during a calculation of the bit node, and of preventing the bit from being input to a calculation of a check node. Thus, it is possible to reduce an amount of calculation by determining a bit node with a low reliability and cancelling a calculation operation of a decoder, and to enhance a decoding performance.

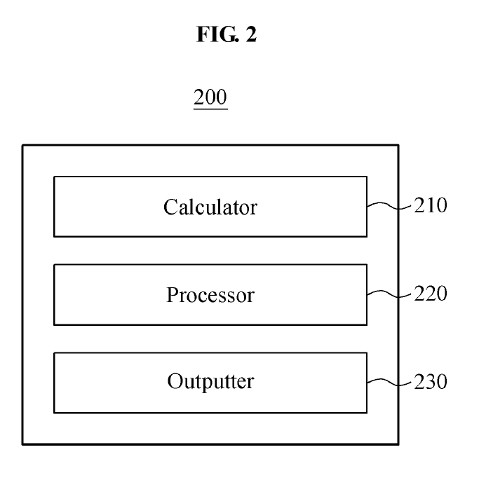

FIG. 2 is a block diagram illustrating an internal configuration of a decoder 200 according to an example embodiment. The decoder 200 of FIG. 2 may include a calculator 210, a processor 220 and an outputter 230. The calculator 210 may function as an instruction calculator and may commonly refer to a part instructing a computer to perform an operation, for example, four fundamental arithmetic operations or a comparison. In the present disclosure, the calculator 210 may comprehensively define a hardware component configured to perform a calculation of a bit node or calculation of a check node for an input frame.

Referring back to FIG. 1, the decoder 200 may store an input frame in a memory in operation 101. A frame may commonly refer to a term indicating a predetermined unit of information transmitted in a data communication, computer graphics, a television broadcast, and the like. The frame may be a collective concept of grouping bits on which a calculation of a check node and a calculation of a bit node are to be performed into specific units in the following process. When a bit node is determined in operation 107 through operation 104 of checking a number of repetitions, the memory may allow the stored frame to be output in operation 108. When the number of repetitions does not reach a threshold, the memory may store the frame so that a calculation of a bit may be additionally performed.

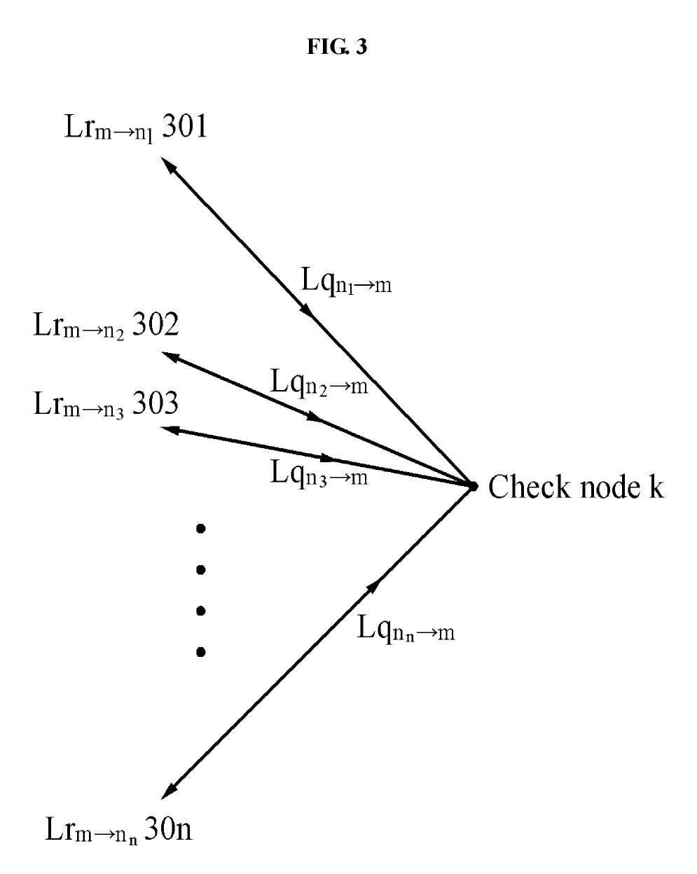

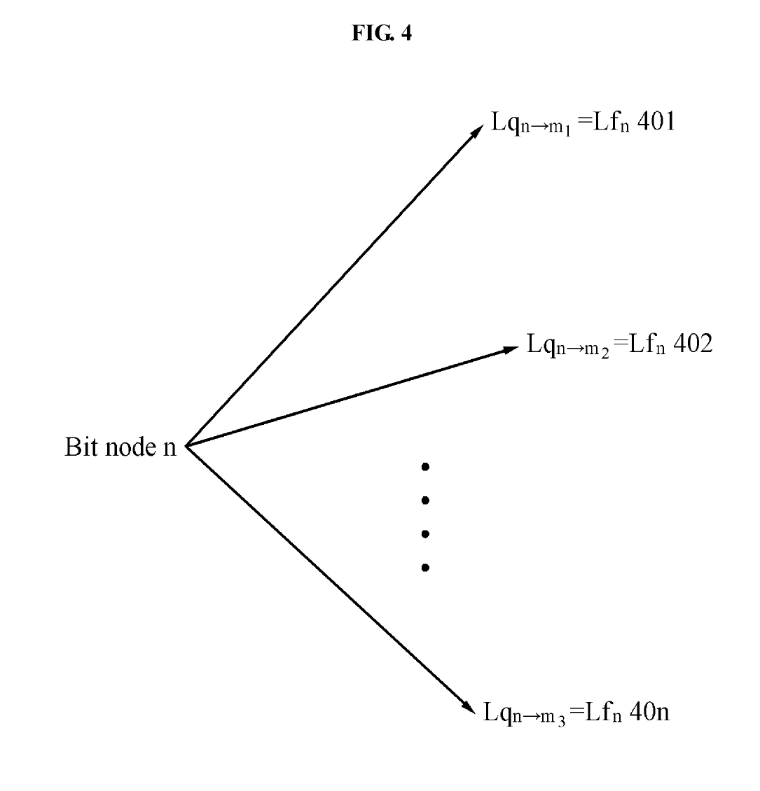

The calculator 210 may repeatedly perform a calculation of a bit node and a calculation of a check node for an input frame. When the frame is input to the calculator 210, the calculator 210 may perform the calculation of the check node and the calculation of the bit node in operations 102 and 103. In the above process, a check node value calculated by the calculation of the check node may be an input value to obtain a bit node value. Also, after the calculation of the bit node, a number of repetitions of the calculations may be checked in operation 104. When the number of repetitions is “1” or less than a threshold, the calculation of the check node may be reperformed, and a bit node value calculated by the calculation of the bit node may be an input value to obtain a check node value. The calculation of the check node and calculation of the bit node will be further described with reference to FIGS. 3 and 4 below. When the calculator 210 performs the calculation of the check node and calculation of the bit node, the processor 220 may check the number of repetitions in operation 104.

The processor 220 may determine the bit node by checking the number of repetitions of the calculation of the check node and calculation of the bit node. The processor 220 may check a number of repetitions of calculations of a check node and a bit node of the decoder 200 of a user. When the number of repetitions is “1,” that is, the calculation is performed once, a bit node value may be input to the calculator 210 so that the calculation of the check node may be reperformed.

The processor 220 may repeat the calculations until the number of repetitions reaches the threshold. The processor 220 may determine, in advance, a threshold for a number of times the calculation of the check node and calculation of the bit node are to be performed. The processor 220 may compare the number of repetitions to the threshold. When the number of repetitions is less than the threshold based on a comparison result, the processor 220 may input the bit node value to the calculator 210. When the number of repetitions is determined to be less than the threshold, the processor 220 may determine whether a code of the bit node is reversed in operation 105.

The processor 220 may determine whether to input the bit node to a next calculation of the check node based on the code of the bit node. For example, when the code of the bit node is reversed, the processor 220 may not input the bit node to the next calculation of the check node. In this example, the code of the bit node may change based on a repetitive calculation process, however, a change in the code of the bit node may be interpreted to indicate that an error is corrected because an original input value is an error bit. Accordingly, because the bit node with the reversed code is a node in which an error is highly likely to occur due to noise, the decoder 200 may determine that a value of a node in which an error occurs is likely to have an influence on a calculation of another node in the repetitive calculation process.

The processor 220 may compare a code of the bit node in a current number of repetitions and a code of the bit node in a previous number of repetitions. The processor 220 may input the bit node in which the code is not reversed to the next calculation of the check node. As described above, in response to a change in a code of a bit node, a corresponding frame may be recognized as a frame with a low reliability. Accordingly, a frame in which the code changes may be excluded from a next calculation process, and thus a complexity of calculations and an amount of calculation may be reduced. To this end, the processor 220 may continue to monitor the code of the bit node. The processor 220 may continue to monitor and compare a code of a bit node in a previous calculation process and a code of a bit node in a current calculation process. Also, the processor 220 may not input a bit with a reversed code to a next calculation process of the check node while performing a decoding process based on a calculation process of a bit node, so as not to perform a bit calculation of a corresponding process. For example, when the number of repetitions is less than the threshold, the processor 220 may determine whether the code of the bit node is reversed in operation 105. When the code is reversed, the processor 220 may not input the bit node to the calculation of the check node in operation 106. When the code is not reversed, the processor 220 may input the bit node to the next calculation of the check node.

The outputter 230 may be configured to output a decoded bit based on the bit node determined to be input. When the number of repetitions reaches the threshold, the processor 220 may determine the bit node in operation 107, and the outputter 230 may output the bit or the frame in operation 108. The code may be generated based on a parity check matrix. The parity check matrix may refer to a matrix indicating a parity check of a linear code. Each row may be represented by a coefficient of an equation representing a parity check. When a parity check matrix of a linear code C is denoted by H, a necessary and sufficient condition to allow a vector v to be a codeword of the linear code C may be represented by “vH^{T}=0” in which T denotes a transposition.

FIG. 3 is a diagram illustrating an example of a structure in which a calculation of a check node is performed according to an example embodiment.

Before the calculation of the check node is performed, an initialization process may be performed. The initialization process may correspond to a process of obtaining a channel estimate value based on a received bit, as shown in Equation 1 below.

$${Lq}_{n -> {m}_{i}} = {Lf}_{n} = - {L}_{c} \cdot {r}_{n} ( {L}_{c} = \frac{2}{{σ}^{2}} ) , \\ n = 0 , 1 , … , N - 1 , \\ i = 1 , 2 , … , deg ( bit node n ) \qquad [ Equation 1 ]$$

When initialization is completed, the calculation of the check node may be performed. A process of calculating a probability that a bit is to come from a single check node in a calculation of the check node is further described with reference to FIG. 3. In other words, the calculation of the check node may an expression that commonly indicates a process of obtaining probabilities that bits are to come from a single check node. When each of nodes is assumed to have n_{dc} row weights, probabilities of bits to come from each of check nodes may be represented as shown in Equation 2 below.

Lr_{k→n}_{ᵢ}=g(Lqₙ_{₁}_{→k}, . . . , Lqₙ_{_{i−1}}_{→k},Lqₙ_{ᵢ₊₁}_{→k}, . . . , Lqₙ_{_{dc}}_{→k}) [Equation 2]

Lr_{k→ni} represented by, for example, reference numerals 301, 302, 303 and 30n of FIG. 3 denotes a probability value input from a k-th check node to an nᵢ-th bit node, and Lq_{ni→k} denotes a probability value input from the nᵢ-th bit node to the k-th check node. The calculator 210 may calculate a probability of a bit to be input to the k-th check node based on the probability values 301 through 30n. The above process of calculating probabilities is represented by arrows as shown in FIG. 3. A function g(a, b) used herein may be defined as shown in Equations 3 and 4 below.

$$\begin{matrix}\begin{matrix}g ( a , b ) = sign ( a ) \times sign ( b ) \times \{ min ( a \vert a \vert , \vert b \vert ) \} + {LUT}_{g} ( a , b ) \\ = ln ( \frac{{e}^{a + b} + 1}{{e}^{a} + {e}^{b}} )\end{matrix} & [ Equation 3 ] \\ {LUT}_{g} ( a , b ) = ln ( 1 + {e}^{- \vert a + b \vert} ) - ln ( 1 + {e}^{- \vert a - b \vert} ) & [ Equation 4 ]\end{matrix}$$

Accordingly, when a single look-up table of LUT(x)=ln(1+e^{-x}) is provided, the above calculation of the check node may be performed. The above equations may be obtained from an existing equation of the calculation of the check node, and accordingly further description thereof is not repeated here.

FIG. 4 is a diagram illustrating an example of a structure in which a calculation of a bit node is performed according to an example embodiment. A calculation of a bit node to obtain a probability of the bit node corresponding to each column after bits connected to each check node are updated will be further described with reference to FIG. 4.

As described above in FIG. 3, Lm_{j→}n denotes a probability value input from an mⱼ-th check node to an n-th bit node, and Lq_{n→mi} denotes a probability value input from the n-th bit node to an mᵢ-th check node. As described above in the initialization process, Lq_{n→mi} is initialized to Lfₙ, which is represented by, for example, reference numerals 401, 402 and 40n of FIG. 4, and a probability value may be calculated by a calculation of a bit node as shown in Equation 5 below. Further description is obvious to one of ordinary skill in the art, and accordingly will be omitted.

$${Lq}_{n -> {m}_{i}} = {Lf}_{n} + {\sum }_{j \neq i} {Lr}_{{m}_{j} -> n} \qquad [ Equation 5 ]$$

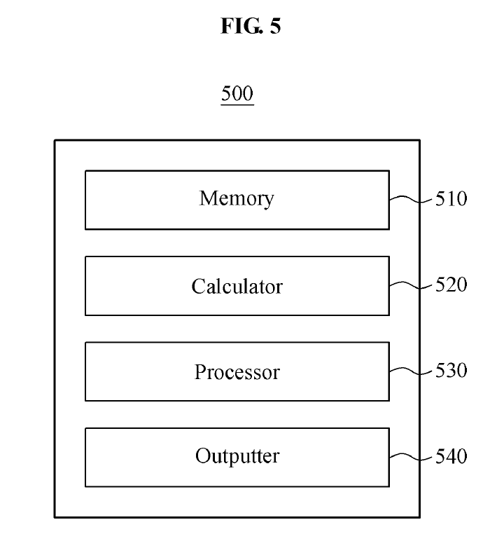

FIG. 5 is a block diagram illustrating an internal configuration of a decoder 500 according to an example embodiment.

The decoder 500 may further include a memory 510 configured to store an input frame. Referring to FIG. 5, the decoder 500 may include the memory 510, a calculator 520, a processor 530 and an outputter 540. The calculator 520, the processor 530 and the outputter 540 may correspond to and may have the same configuration as the calculator 210, the processor 220 and the outputter 230 in the decoder 200 of FIG. 2, respectively. In an example, the decoder 500 may store the input frame as described above and a bit node that is currently calculated, and may allow the calculator 520 to perform a next calculation of the check node. In another example, a code of a bit node monitored by the processor 530 may be temporarily stored and the processor 530 may be allowed to use a stored value for a comparison to a code of a bit node in a next calculation. Also, the memory 510 may store a threshold that is set by the decoder 500, and may allow the processor 530 to compare a number of repetitions to the threshold.

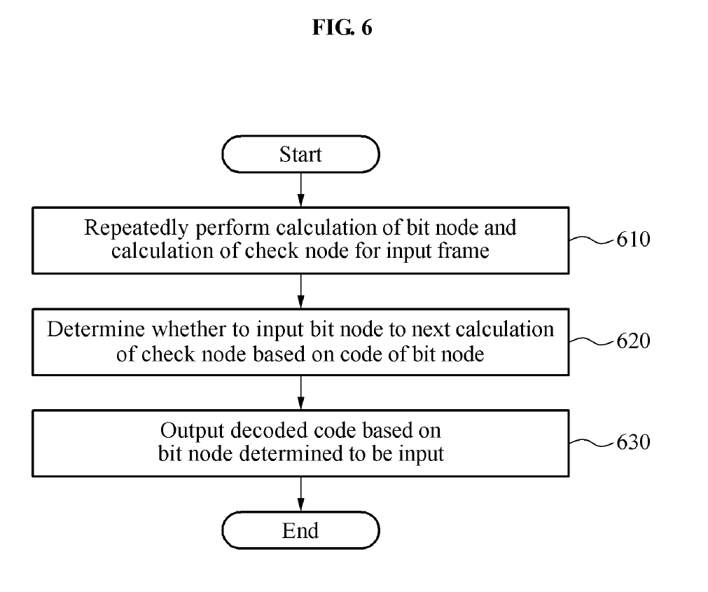

FIG. 6 is a flowchart illustrating an example of a decoding method according to an example embodiment.

The decoding method may include storing an input frame in a memory. A frame may commonly refer to a term indicating a predetermined unit of information transmitted in a data communication, computer graphics, a television broadcast, and the like. The frame may be a collective concept of grouping bits on which a calculation of a check node and a calculation of a bit node are to be performed into specific units in the following process. When a bit node is determined through an operation of checking a number of repetitions, a processor may allow the stored frame to be output. When the number of repetitions does not reach a threshold, the frame may be stored in the memory so that a calculation of bits may be additionally performed.

The decoding method may include repeatedly performing a calculation of a bit node and a calculation of a check node for an input frame in operation 610. When the frame is input to the calculator 210, the calculator 210 may repeatedly perform the calculation of the check node and the calculation of the bit node. In the above process, a check node value calculated by the calculation of the check node may be used as an input value to obtain a bit node value. Also, after the calculation of the bit node, a number of repetitions of the calculations may be checked. When the number of repetitions is “1” or less than a threshold, the calculation of the check node may be reperformed, and a bit node value calculated by the calculation of the bit node may be used as an input value to obtain a check node value. The calculation of the check node and calculation of the bit node have been described in detail with reference to FIGS. 3 and 4, and accordingly further description is omitted here. When the calculator 210 performs the calculation of the check node and calculation of the bit node, the processor 220 may check the number of repetitions.

The decoding method may further include determining the bit node by checking the number of repetitions of the calculation of the check node and calculation of the bit node. The processor 220 may check a number of repetitions of calculations of a check node and a bit node of the decoder 200 of a user. When the number of repetitions is “1,” that is, the calculation is performed once, a bit node value may be input to the calculator 210 so that the calculation of the check node may be reperformed.

The decoding method may further include repeating the calculations until the number of repetitions reaches the threshold. The processor 220 may determine, in advance, a threshold for a number of times the calculation of the check node and calculation of the bit node are to be performed. The processor 220 may compare the number of repetitions to the threshold. When the number of repetitions is less than the threshold based on a comparison result, the processor 220 may input the bit node value to the calculator 210. When the number of repetitions is determined to be less than the threshold, the processor 220 may determine whether a code of the bit node is reversed.

The decoding method may include determining whether to input the bit node to a next calculation of the check node based on the code of the bit node in operation 620. Also, the decoding method may further include, when the code is reversed, determining not to input the bit node to the next calculation of the check node. The code of the bit node may change based on a repetitive calculation process, however, a change in the code of the bit node may be interpreted to indicate that an error is corrected because an original input value is an error bit. Accordingly, because the bit node with the reversed code is a node in which an error is highly likely to occur due to noise, the decoding method may include determining that a value of a node in which an error occurs is likely to have an influence on a calculation of another node in the repetitive calculation process.

The processor 220 may compare a code of a bit node in a current number of repetitions and a code of the bit node in a previous number of repetitions. The processor 220 may input the bit node in which the code is not reversed to a next calculation of a check node. As described above, in response to a change in a code of a bit node, a corresponding frame may be recognized as a frame with a low reliability. Accordingly, a frame in which the code changes may be excluded from a next calculation process, and thus a complexity of calculations and an amount of calculation may be reduced. To this end, the processor 220 may continue to monitor the code of the bit node. The processor 220 may continue to monitor and compare a code of a bit node in a previous calculation process and a code of a bit node in a current calculation process. Also, the processor 220 may not input a bit with a reversed code to a next calculation process of the check node while performing a decoding process based on a calculation process of a bit node, so as not to perform a bit calculation of a corresponding process. For example, when the number of repetitions is less than the threshold, the processor 220 may determine whether the code of the bit node is reversed. When the code is reversed, the processor 220 may not input the bit node to the calculation of the check node. When the code is not reversed, the processor 220 may input the bit node to the next calculation of the check node.

The decoding method of FIG. 6 may include outputting a decoded bit based on the bit node determined to be input in operation 630. When the number of repetitions reaches the threshold, the processor 220 may determine the bit node, and the outputter 230 may output the bit or the frame. The code may be generated based on a parity check matrix. The parity check matrix may refer to a matrix indicating a parity check of a linear code. Each row may be represented by a coefficient of an equation representing a parity check. When a parity check matrix of a linear code C is denoted by H, a necessary and sufficient condition to allow a vector v to be a codeword of the linear code C may be represented by “vH^{T}=0” in which T denotes a transposition.

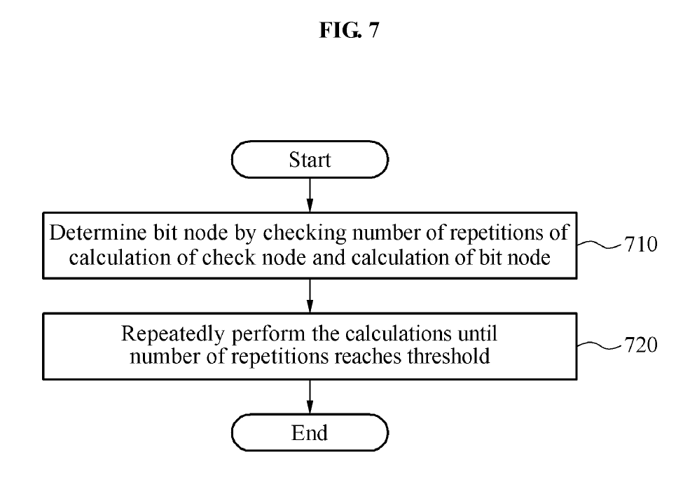

FIG. 7 is a flowchart illustrating another example of a decoding method according to an example embodiment.

The decoding method may include determining the bit node by checking the number of repetitions of the calculation of the check node and calculation of the bit node in operation 710. The processor 220 may check a number of repetitions of calculations of a check node and a bit node of the decoder 200 of a user. When the number of repetitions is “1,” that is, the calculation is performed once, a bit node value may be input to the calculator 210 so that the calculation of the check node may be reperformed.

The decoding method may include repeating the calculations until the number of repetitions reaches the threshold in operation 720. The processor 220 may determine, in advance, a threshold for a number of times the calculation of the check node and calculation of the bit node are to be performed. The processor 220 may compare the number of repetitions to the threshold. When the number of repetitions is less than the threshold based on a comparison result, the processor 220 may input the bit node value to the calculator 210. When the number of repetitions is determined to be less than the threshold, the processor 220 may determine whether a code of the bit node is reversed.

The decoding method of FIG. 7 may further include storing the input frame in a memory. In an example, the decoding method of FIG. 7 may further include storing the input frame as described above, and may also include storing a bit node that is currently calculated and allowing the calculator 520 to perform a next calculation of the check node. In another example, a code of a bit node monitored by the processor 530 may be temporarily stored and the processor 530 may be allowed to use a stored value for a comparison to a code of a bit node in a next calculation. Also, the memory 510 may store a threshold that is set by the decoder 500, and may allow the processor 530 to compare a number of repetitions to the threshold.

The components described in the example embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The example embodiments described herein may be implemented using hardware components, software components, and/or a combination thereof. For example, the processing device and the component described herein may be implemented using one or more general-purpose or special purpose computers, such as, for example, a processor, a controller and an arithmetic logic unit (ALU), a digital signal processor, a microcomputer, a FPGA, a programmable logic unit (PLU), a microprocessor, or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will be appreciated that a processing device may include multiple processing elements and/or multiple types of processing elements. For example, a processing device may include multiple processors or a processor and a controller. In addition, different processing configurations are possible, such as parallel processors.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A decoder that is at least temporarily implemented by a processor of a computing device, the decoder comprising:
a calculator configured to repeatedly perform a calculation of a bit node and a calculation of a check node for an input frame;
a processor configured to determine whether to input the bit node to a next calculation of the check node based on a code of the bit node; and
an outputter configured to output a decoded code based on the bit node determined to be input.

2. The decoder of claim 1, wherein the processor is further configured to determine the bit node by checking a number of repetitions of the calculation of the check node and the calculation of the bit node.

3. The decoder of claim 2, wherein the processor is further configured to repeatedly perform the calculation of the check node and the calculation of the bit node until the number of repetitions reaches a threshold.

4. The decoder of claim 1, wherein when the code is reversed, the bit node is determined not to be input to the next calculation of the check node.

5. The decoder of claim 4, wherein the processor is further configured to compare a code of the bit node in a current number of repetitions and a code of the bit node in a previous number of repetitions.

6. The decoder of claim 1, wherein a bit node in which a code is not reversed is input to the next calculation of the check node.

7. The decoder of claim 1, wherein the code is generated based on a parity check matrix.

8. The decoder of claim 1, further comprising:
a memory configured to store the input frame.

9. A decoding method comprising:
repeatedly performing a calculation of a bit node and a calculation of a check node for an input frame;
determining whether to input the bit node to a next calculation of the check node based on a code of the bit node; and
outputting a decoded code based on the bit node determined to be input.

10. The decoding method of claim 9, further comprising:
determining the bit node by checking a number of repetitions of the calculation of the check node and the calculation of the bit node.

11. The decoding method of claim 10, further comprising:
repeatedly performing the calculation of the check node and the calculation of the bit node until the number of repetitions reaches a threshold.

12. The decoding method of claim 9, further comprising:
when the code is reversed, determining not to input the bit node to the next calculation of the check node.

13. The decoding method of claim 12, further comprising:
comparing a code of the bit node in a current number of repetitions and a code of the bit node in a previous number of repetitions.

14. The decoding method of claim 9, further comprising:
inputting a bit node in which a code is not reversed to the next calculation of the check node.

15. The decoding method of claim 9, further comprising:
generating the code based on a parity check matrix.

16. The decoding method of claim 9, further comprising:
storing the input frame in a memory.

17. A non-transitory computer-readable storage medium storing a program for causing a processor to perform the decoding method of claim 9.
